(19) United States
(12) Patent Application Publication
(10) Pub. No.: US 2024/0161844 A1
(43) Pub. Date: May 16, 2024

(54) ANTIFUSE-TYPE NON-VOLATILE MEMORY AND CONTROL METHOD THEREOF

(71) Applicant: eMemory Technology Inc., Hsin-Chu (TW)

(72) Inventors: Chia-Fu CHANG, Hsinchu County (TW); Jen-Yu PENG, Hsinchu County (TW); Ming-Hsuan TAN, Hsinchu County (TW)

(21) Appl. No.: 18/370,412

(22) Filed: Sep. 20, 2023

Related U.S. Application Data
(60) Provisional application No. 63/424,966, filed on Nov. 14, 2022.

(51) Int. Cl. G11C 17/18; G11C 17/16

(52) U.S. Cl. CPC G11C 17/18; G11C 17/16

(57) ABSTRACT

An antifuse-type non-volatile memory and a control method for the antifuse-type non-volatile memory are provided. During a program action of a program cycle, a timing controller generates a timing control signal. According to the timing control signal, a word line driver is controlled to provide an on voltage and an off voltage to an activated word line. In a total time period of plural on periods, the program current is sufficient to rupture a gate oxide layer of an antifuse transistor in the selected memory cell, and a heating process is completed. Consequently, the gate oxide layer of the antifuse transistor is in a solid rupture state. Consequently, the program action can be successfully performed on the selected memory cell.

### FIELD OF THE INVENTION

The present invention relates to a non-volatile memory, and more particularly to an antifuse-type non-volatile memory and a control method for the antifuse-type non-volatile memory.

### BACKGROUND OF THE INVENTION

The non-volatile memories may be classified into a multi-time programming memory (also referred as a MTP memory), a one time programming memory (also referred as an OTP memory) and a mask read only memory (also referred as a Mask ROM).

Generally, the MTP memory can be programmed many times, and the stored data of the MTP memory can be modified many times. On the contrary, the OTP memory can be programmed once. After the OTP memory is programmed, the stored data cannot be modified. Moreover, after the Mask ROM leaves the factory, all stored data have been recorded therein. The user is only able to read the stored data from the Mask ROM, but is unable to program the Mask ROM.

For example, an antifuse-type non-volatile memory is a one of the OTP memories. Before the memory cell of the antifuse-type non-volatile memory is programmed, the memory cell of the antifuse-type non-volatile memory is in a high-resistance storage state. After the memory cell of the antifuse-type non-volatile memory is programmed, the memory cell of the antifuse-type non-volatile memory is in a low-resistance storage state. In addition, after the memory cell of the antifuse-type non-volatile memory is programmed, the stored data cannot be modified.

### SUMMARY OF THE INVENTION

An embodiment of the present invention provides an antifuse-type non-volatile memory. The antifuse-type non-volatile memory includes an antifuse-type memory cell array and a control circuit. The antifuse-type memory cell array includes a first memory cell. The first memory cell is connected with an antifuse control line. A first word line and a first bit line. The first memory cell includes an antifuse transistor and a select transistor. A first drain/source terminal of the select transistor is connected with the first bit line. A gate terminal of the select transistor is connected with the first word line. A first drain/source terminal of the antifuse transistor is coupled to a second drain/source terminal of the select transistor. A gate terminal of the antifuse transistor is connected with the antifuse control line. The control circuit includes an oscillator, a program voltage generator, a timing controller, a word line driver and a bit line driver. The oscillator generates a clock signal. The program voltage generator includes a charge pump. The charge pump is connected with the oscillator to receive the clock signal. When a program action is performed, a supply voltage is boosted to a program voltage by the charge pump according to the clock signal, and the program voltage is provided to the antifuse control line. The timing controller is connected with the oscillator. The timing controller receives the clock signal and generates a timing control signal. The word line driver is connected with the first word line of the antifuse-type memory cell array. The word line driver is connected with the timing controller to receive the timing control signal. The bit line driver is connected with the first bit line of the antifuse-type memory cell array. In a program cycle of the program action, the first word line is activated by the word line driver, and the first bit line is activated by the bit line driver, so that the first memory cell is a selected memory cell. In the program cycle of the program action, the word line driver issues a pulse signal to the first word line according to the timing control signal. A first level of the pulse signal is an on voltage. A second level of the pulse signal is an off voltage. After the program cycle, a storage state of the first memory cell is switched from a high-resistance storage state to a low-resistance storage state.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A is a schematic circuit diagram illustrating an antifuse-type non-volatile memory according to a first embodiment of the present invention;

FIG. 1B is a schematic timing waveform diagram illustrating associated signals when the memory cell of the antifuse-type non-volatile memory of the first embodiment undergoes the program action;

FIG. 1C is a schematic timing waveform diagram illustrating associated signals when the memory cell of the antifuse-type non-volatile memory of the first embodiment undergoes the program action and the driving capability of the charge pump is weaker;

FIG. 2 schematically illustrates the IC chip layout structure of a small-capacity antifuse-type non-volatile memory;

FIG. 3A is a schematic circuit diagram illustrating an antifuse-type non-volatile memory according to a second embodiment of the present invention;

FIG. 3B is a schematic timing waveform diagram illustrating associated signals when the memory cell of the antifuse-type non-volatile memory of the second embodiment undergoes the program action;

FIG. 3C is a schematic timing waveform diagram illustrating another signal when the memory cell of the antifuse-type non-volatile memory of the second embodiment undergoes the program action;

FIG. 4A is a schematic circuit diagram illustrating an antifuse-type non-volatile memory according to a third embodiment of the present invention;

FIG. 4B is a schematic timing waveform diagram illustrating associated signals when the memory cell of the antifuse-type non-volatile memory of the third embodiment undergoes the program action; and

FIG. 5 is a schematic circuit diagram illustrating an antifuse-type non-volatile memory according to a fourth embodiment of the present invention.

### DETAILED DESCRIPTION OF PREFERRED EMBODIMENTS

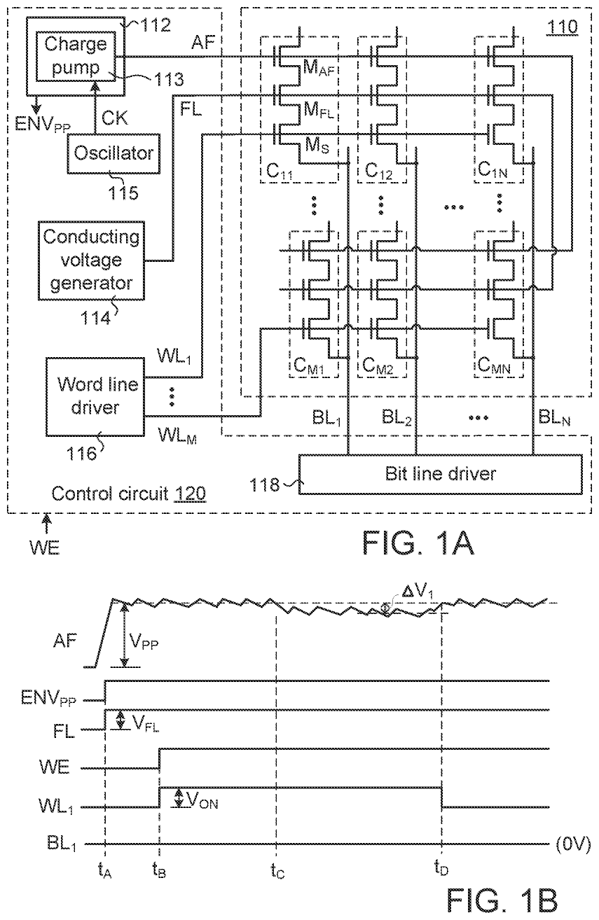

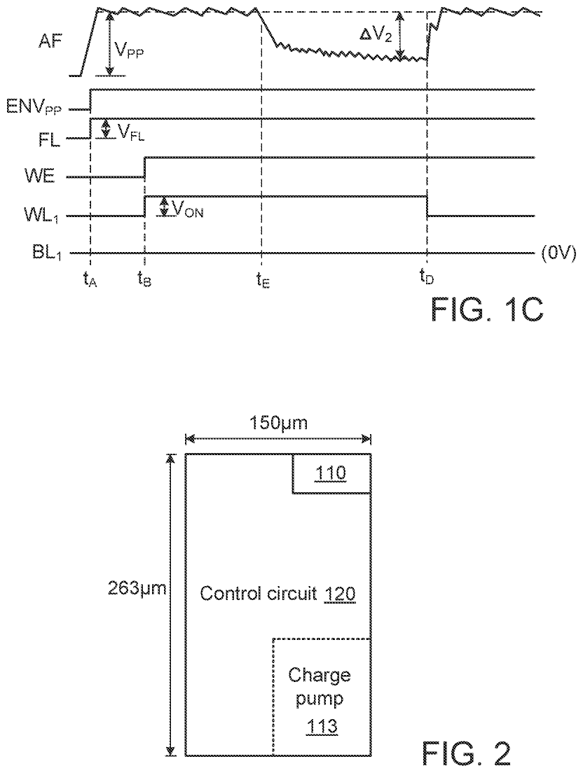

FIG. 1A is a schematic circuit diagram illustrating an antifuse-type non-volatile memory according to a first embodiment of the present invention. As shown in FIG. 1A, the antifuse-type non-volatile memory comprises an antifuse-type memory cell array 110 and a control circuit 120.

The antifuse-type memory cell array 110 comprises M×N antifuse-type non-volatile memory cells C₁₁˜C_{MN}, wherein M and N are positive integers. The antifuse-type memory cell array 110 is connected with an antifuse control line AF, a following control line FL, M word lines WL₁˜WL_{M} and N bit lines BL₁˜BL_{N}. The N memory cells C₁₁˜C_{1N} in the first row are connected with the antifuse control line AF, the following control line FL and the word line WL₁. The N memory cells C₁₁˜C_{1N} in the first row are respectively connected with the bit lines BL₁˜BL_{N}. The rest may be deduced by analogy. The N memory cells C_{M1}˜C_{MN} in the M-th row are connected with the antifuse control line AF, the following control line FL and the word line WL_{M}. The N memory cells C_{M1}˜C_{MN} in the M-th row are respectively connected with the N bit lines BL₁˜BL_{N}.

The structures of the M×N memory cells C₁₁˜C_{MN} are identical. Take the memory cell C₁₁ for example. The memory cell C₁₁ may be referred as a 3T memory cell. That is, the memory cell C₁₁ comprises an antifuse transistor M_{AF}, a following transistor M_{FL} and a select transistor M_{S}.

The first drain/source terminal of the select transistor M_{S} is connected with the bit line BL₁. The gate terminal of the select transistor M_{S} is connected with the word line WL₁. The first drain/source terminal of the following transistor M_{FL} is connected with the second drain/source terminal of the select transistor M_{S}. The gate terminal of the following transistor M_{FL} is connected with the following control line FL. The first drain/source terminal of the antifuse transistor M_{AF} is connected with the second drain/source terminal of the following transistor M_{FL}. The gate terminal of the antifuse transistor M_{AF} is connected with the antifuse control line AF. The second drain/source terminal of the antifuse transistor M_{AF} is in a floating state.

The control circuit 120 comprises a program voltage generator 112, a conducting voltage generator 114, a word line driver 116 and a bit line driver 118. The program voltage generator 112 is connected with the antifuse control line AF. The conducting voltage generator 114 is connected with the following control line FL. The word line driver 116 is connected with the word lines WL₁˜WL_{M}. The bit line driver 118 is connected with the bit lines BL₁˜BL_{N}.

When a program action is performed, the program voltage generator 112 issues a program voltage V_{PP} to the antifuse control line AF, and the conducting voltage generator 114 issues a conducting voltage V_{FL} to the following control line FL. In addition, one of the M word lines WL₁˜WL_{M} is activated by the word line driver 116. Consequently, the row of the antifuse-type memory cell array 110 corresponding to the activated word line is determined as the selected row. In addition, a specified bit line of the bit lines BL₁˜BL_{N} is activated by the bit line driver 118. According to the activated word line and the activated bit line, the corresponding memory cell in the selected row is determined as the selected memory cell. Consequently, the program action is performed on the selected memory cell.

For example, when the word line WL₁ is activated by the word line driver 116, a fixed on voltage V_{ON} is provided to the word line WL₁. When the bit line BL₁ is activated by the bit line driver 118, a ground voltage (0V) is provided to the bit line BL₁. Consequently, the memory cell C₁₁ is the selected memory cell. In an embodiment, the program voltage V_{PP} is 6V, the conducting voltage V_{FL} is 2.6V, and the on voltage V_{ON} is 1.6V. It is noted that the magnitudes of the program voltage V_{PP}, the conducting voltage V_{FL} and the on voltage V_{ON} are not restricted.

Among the bias voltages provided to the antifuse-type non-volatile memory, the value of the program voltage V_{PP} is the highest. Consequently, a charge pump 113 with the better driving capability is included in the program voltage generator 112 to generate the program voltage V_{PP}. By the charge pump 113, a supply voltage (e.g., 3.3V) provided by the antifuse-type non-volatile memory is boosted to a higher program voltage V_{Pp}.

The control circuit 120 further comprises an oscillator 115. The oscillator 115 generates a clock signal CK to the charge pump 113. According to the clock signal CK, the supply voltage is boosted to the higher program voltage V_{PP}.

Moreover, since the conducting voltage V_{FL} is lower, the conducting voltage generator 114 may be implemented with a low-dropout regulator LDO. Of course, any other appropriate voltage generators are feasible for generating the conducting voltage V_{FL}.

FIG. 1B is a schematic timing waveform diagram illustrating associated signals when the memory cell of the antifuse-type non-volatile memory of the first embodiment undergoes the program action. For example, the program action is performed on the memory cell C₁₁. Firstly, the antifuse-type non-volatile memory enters a program mode, and the program voltage generator 112 is enabled.

At the time point t_{A}, a program voltage enable signal ENV_{PP} is activated (e.g., switched from a low logic level state to a high logic level state). Meanwhile, the program voltage V_{PP} outputted from the charge pump 113 of the program voltage generator 112 to the antifuse control line AF reaches a predetermined voltage (e.g., 6V). At the same time, the conducting voltage generator 114 issues the conducting voltage V_{FL} to the following control line FL.

At the time point t_{B}, a write enable signal WE is activated (e.g., switched from a low logic level state to a high logic level state). Meanwhile, the program action on the antifuse-type non-volatile memory can be started. For example, the word line driver 116 is operated according to the program voltage enable signal ENV_{PP} and the write enable signal WE. Meanwhile, the word line WL₁ is activated by the word line driver 116, and the on voltage V_{ON} is provided to the word line WL₁. The other word lines WL₂˜WL_{M} are not activated by the word line driver 116. That is, the word line driver 116 provides an off voltage V_{OFF} to the other word lines WL₂˜WL_{M}. Consequently, the first row of the antifuse-type memory cell array 110 is the selected row. At the same time, the bit line BL₁ is activated by the bit line driver 118, and the bit line driver 118 provides the ground voltage (0V) to the bit line BL₁. The other bit lines BL₂˜BL_{N} are not activated by the bit line driver 118. Moreover, the other bit lines BL₂˜BL_{N} are in the floating state. Consequently, the memory cell C₁₁ in the selected row is the selected memory cell, and the other memory cells C₁₂˜C_{1N} in the selected row are unselected memory cells. For example, the off voltage V_{OFF} is the ground voltage (0V).

In the above embodiment, the bit lines BL₂˜BL_{N} are in the floating state, and thus the bit lines BL₂˜BL_{N} are not activated. In some other embodiments, the bit lines are inactivated by using another method. For example, the bit line driver 118 provides the ground voltage (0V) to activate the bit line BL₁, and the bit line driver 118 provides a higher voltage (e.g., 3.3V) to inactivate the bit lines BL₂˜BL_{N}.

In addition, the program action is performed in plural program cycles. The time length between the time point t_{B} and the time point t_{D} is equal to one program cycle. In the program cycle, the voltage provided to the word line WL₁ is maintained in the on voltage V_{ON}. In the program cycle, the antifuse control line AF receives the program voltage V_{PP}, the following control line FL receives the conducting voltage V_{FL}, the word line WL₁ receives the on voltage V_{ON}, and the bit line BL₁ receives ground voltage (0V). In the selected memory cell C₁₁, the select transistor M_{S} is turned on, and the following transistor M_{FL} is in a conducting state. Consequently, the select transistor M_{S} is coupled to the antifuse transistor M_{AF}. In addition, the ground voltage (0V) of the bit line BL₁ is transferred to the first drain/source terminal of the antifuse transistor M_{AF}. Consequently, the voltage stress between the gate terminal and the first drain/source terminal of the antifuse transistor M_{AF} is equal to the program voltage V_{PP}.

The gate oxide layer of the antifuse transistor M_{AF} receives the higher voltage stress. Consequently, at the time point t_{C}, the gate oxide layer of the antifuse transistor M_{AF} is ruptured. Consequently, the storage state of the selected memory cell C₁₁ is switched from a high-resistance storage state to a low-resistance storage state. Similarly, after the time point t_{D}, the word line driver 116 activates another word line, and the bit line driver 118 activates another bit line. Consequently, another program cycle is started, and the program action is performed on another selected memory cell.

Please refer to FIG. 1B again. Before the time point t_{C}, the gate oxide layer of the antifuse transistor M_{AF} has not been ruptured. Consequently, no program current is generated in the region between the antifuse control line AF and the bit line BL₁. At the time point t_{C}, the gate oxide layer of the antifuse transistor M_{AF} is ruptured. Consequently, a program current is generated in the region between the antifuse control line AF and the bit line BL₁ until the time point t_{D}. At the time point to, the word line driver 116 provides the off voltage V_{OFF} to the word line WL₁. Consequently, the select transistor M_{S} is turned off, and the selected memory cell C₁₁ stops generating the program current. Meanwhile, the program cycle is ended.

As mentioned above, before the time point t_{C}, the gate oxide layer of the antifuse transistor M_{AF} in the selected memory cell C₁₁ has not been ruptured. Since no program current is generated, the program voltage V_{PP} provided by the charge pump 113 is more stable.

The charge pump 113 has the better driving capability. Consequently, in case that the gate oxide layer of the antifuse transistor M_{AF} in the selected memory cell C₁₁ is ruptured and the program current through the selected memory cell C₁₁ is generated after the time point t_{C}, the program voltage V_{PP} from the charge pump 113 is slightly decreased by a voltage drop ΔV₁. That is, in the time interval between the time point t_{C} and the time point t_{D}, the voltage drop of the program voltage V_{PP} is ΔV₁. However, since the driving capability of the charge pump 113 is strong enough to keep the sufficient program current through the selected memory cell C₁₁, the time interval between the time point t_{C} and the time point to may be regarded as a heating process of the program cycle, to strengthen a filament formed through the gate oxide layer. Due to the sufficient program current, the gate oxide layer of the antifuse transistor M_{AF} is in a solid rupture state. Consequently, it is assured that the selected memory cell C₁₁ can be switched to the low-resistance storage state.

Generally, after the gate oxide layer of the antifuse transistor M_{AF} in the selected memory cell C₁₁ is ruptured and the program current is generated, the voltage drop of the program voltage V_{PP} is related to the driving capability of the charge pump 113. In case that the driving capability of the charge pump 113 is stronger, the voltage drop of the program voltage V_{PP} is lower. In case that the driving capability of the charge pump 113 is weaker, the voltage drop of the program voltage V_{PP} is higher.

FIG. 1C is a schematic timing waveform diagram illustrating associated signals when the memory cell of the antifuse-type non-volatile memory of the first embodiment undergoes the program action and the driving capability of the charge pump is weaker. Similarly, the program action is performed on the selected memory cell C₁₁ of the antifuse-type non-volatile memory.

Before the time point t_{E}, the gate oxide layer of the antifuse transistor M_{AF} in the selected memory cell C₁₁ has not been ruptured. Since no program current is generated, the program voltage V_{PP} provided by the charge pump 113 is more stable.

The charge pump 113 has the weaker driving capability. Consequently, in case that the gate oxide layer of the antifuse transistor M_{AF} in the selected memory cell C₁₁ is ruptured and the program current is generated after the time point t_{E}, the program voltage V_{PP} from the charge pump 113 is largely decreased by a voltage drop ΔV₂. In other words, the time interval between the time point t_{E} and the time point to may be regarded as a heating process of the program cycle. Since the driving capability of the charge pump 113 is weaker, the voltage drop ΔV₂ of the program voltage V_{PP} is obvious. Consequently, the program current is very low. After the heating process, the gate oxide layer of the antifuse transistor M_{AF} cannot reach the solid rupture state. In other words, the selected memory cell C₁₁ is in a program failure condition.

FIG. 2 schematically illustrates the IC chip layout structure of a small-capacity antifuse-type non-volatile memory. For example, the antifuse-type non-volatile memory comprises a control circuit 120 and an antifuse-type memory cell array 110 with the capacity of 1 k bytes. In order to design the charge pump 113 with better driving capability, the size of the charge pump 113 would be larger, which occupies a great portion of the IC chip area.

Generally, the fabricating cost of the IC chip is increased with the increasing size of the IC chip. In case that the small-capacity antifuse-type non-volatile memory is equipped with the charge pump 113 with better driving capability, the size of the overall IC chip cannot be further reduced. Since the fabricating cost cannot be reduced, the competitive advantage will be lost.

In other words, it is preferred that the small-capacity antifuse-type non-volatile memory is equipped with the charge pump 113 with weaker driving capability. In case that the control circuit and the control method are specially designed, the antifuse-type non-volatile memory can be operated normally. Since the antifuse-type non-volatile memory has the smaller IC chip size and the reduced cost, the competitive advantage will be increased.

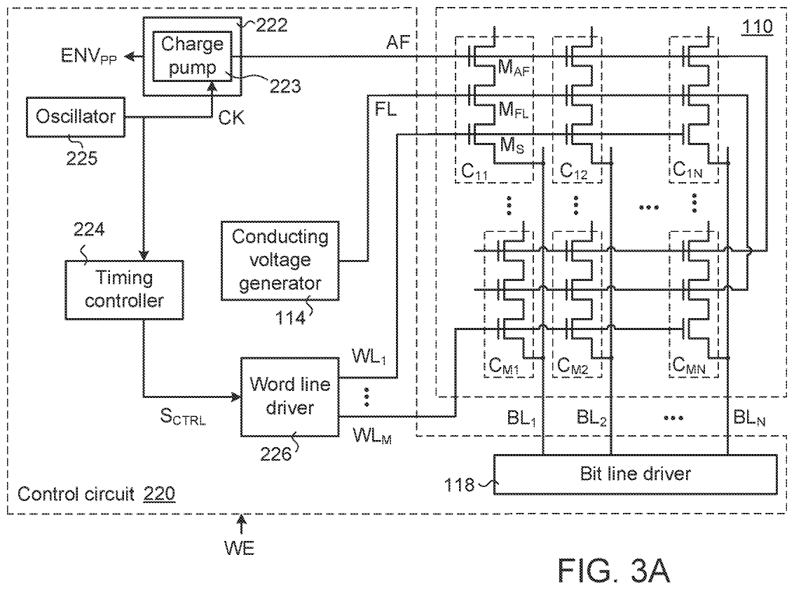

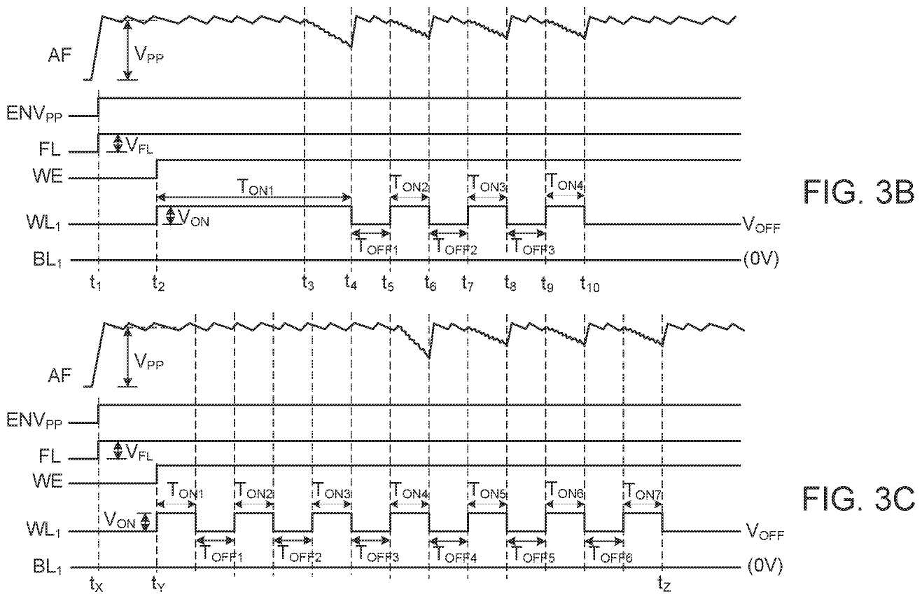

FIG. 3A is a schematic circuit diagram illustrating an antifuse-type non-volatile memory according to a second embodiment of the present invention. As shown in FIG. 3A, the antifuse-type non-volatile memory comprises an antifuse-type memory cell array 110 and a control circuit 220. The antifuse-type memory cell array 110 comprises M×N antifuse-type non-volatile memory cells C₁₁˜C_{MN}, wherein M and N are positive integers. The structure of the antifuse-type non-volatile memory 110 is similar to that of the antifuse-type non-volatile memory 110 shown in FIG. 1A, and not redundantly described herein.

The control circuit 220 comprises a program voltage generator 222, a conducting voltage generator 114, an oscillator 225, a timing controller 224, a word line driver 226 and a bit line driver 118. The program voltage generator 222 is connected with the antifuse control line AF. The conducting voltage generator 114 is connected with the following control line FL. The word line driver 226 is connected with the word lines WL₁˜WL_{M}. The bit line driver 118 is connected with the bit lines BL₁˜BL_{N}. Similarly, the conducting voltage generator 114 is implemented by a low-dropout regulator (LDO). The conducting voltage generator 114 issues the conducting voltage V_{FL}.

Moreover, a charge pump 223 with the weaker driving capability is included in the program voltage generator 222. The charge pump 223 is connected with the oscillator 225. By the charge pump 223, the supply voltage is boosted to the program voltage V_{PP} according to the clock signal CK provided by the oscillator 225. For example, the program voltage V_{PP} is 6V, and the conducting voltage V_{FL} is 2.6V.

When a program action is performed, the program voltage generator 222 issues a program voltage V_{PP} to the antifuse control line AF, and the conducting voltage generator 114 issues a conducting voltage V_{FL} to the following control line FL. In addition, one of the M word lines WL₁˜WL_{M} is activated by the word line driver 226. Consequently, the row of the antifuse-type memory cell array 110 corresponding to the activated word line is determined as the selected row. In addition, a specified bit line of the bit lines BL₁˜BL_{N} is selectively activated by the bit line driver 118. According to the activated word line and the activated bit line, the corresponding memory cell in the selected row is determined as the selected memory cell. Consequently, the program action is performed on the selected memory cell.

In the second embodiment, the timing controller 224 receives the clock signal CK. When the program action is performed, a timing control signal S_{CTRL} is generated, and the timing control signal S_{CTRL} is issued to the word line driver 226. In the program cycle of the program action, the word line driver 226 generates a pulse signal according to the timing control signal S_{CTRL}. The pulse signal is switched between the on voltage V_{ON} and the off voltage V_{OFF}. The pulse signal is provided to activate word line. For example, the on voltage V_{ON} is a fixed voltage (1.6V), and the off voltage V_{OFF} is 0V. In other words, the amplitude of the pulse signal generated by the word line driver 226 is not changed. Moreover, the first level state of the pulse signal is the on voltage V_{ON} (e.g., 1.6V), and the second level state of the pulse signal is the off voltage V_{OFF} (e.g., 0V).

FIG. 3B is a schematic timing waveform diagram illustrating associated signals when the memory cell of the antifuse-type non-volatile memory of the second embodiment undergoes the program action. For example, the program action is performed on the memory cell C₁₁.

Firstly, the antifuse-type non-volatile memory enters a program mode, and the program voltage generator 222 is enabled.

At the time point t₁, a program voltage enable signal ENV_{PP} is activated. Meanwhile, the program voltage V_{PP} outputted from the charge pump 223 of the program voltage generator 222 to the antifuse control line AF reaches a predetermined voltage (e.g., 6V). At the same time, the conducting voltage generator 114 issues the conducting voltage V_{FL} to the following control line FL.

At the time point t₂, a write enable signal WE is activated. Meanwhile, the program action on the antifuse-type non-volatile memory can be started. The time interval between the time points t₂ and t₁₀ may be regarded as a program cycle. For example, in the program cycle, the word line WL₁ is activated by the word line driver 226, but the other word lines WL₂˜WL_{M} are not activated. In addition, the bit line BL₁ is activated by the bit line driver 118, but the other bit lines BL₂˜BL_{N} are not activated. Under this circumstance, the first row of the antifuse-type memory cell array 110 is the selected row. Consequently, the memory cell C₁₁ in the selected row is the selected memory cell, and the other memory cells C₁₂˜C_{1N} in the selected row are unselected memory cells.

In the program cycle between the time point t₂ and the time point t₁₀, the voltage provided from the word line driver 226 to the activated word line WL₁ is switched between the on voltage V_{ON} and the off voltage V_{OFF} according to the timing control signal S_{CTRL}. In other words, the program cycle is divided into plural on periods and plural off periods by the word line driver 226. In the on periods T_{ON1}, T_{ON2}, T_{ON3} and T_{ON4}, the word line driver 226 provides the on voltage V_{ON} to the activated word line WL₁. In the off periods T_{OFF1}, T_{OFF2} and T_{OFF3}, the word line driver 226 provides the off voltage V_{OFF} to the activated word line WL₁. Please refer to FIG. 3B again. In the on period T_{ON1} between the time points t₂ and t₄, the word line driver 226 provides the on voltage V_{ON} to word line WL₁. Consequently, the select transistor M_{S} is turned on. Before the time point t₃, the gate oxide layer of the antifuse transistor M_{AF} has not been ruptured. Consequently, no program current is generated in the region between the antifuse control line AF and the bit line BL₁. At the time point t₃, the gate oxide layer of the antifuse transistor M_{AF} is ruptured. Consequently, a program current is generated in the region between the antifuse control line AF and the bit line BL₁. As mentioned above, when the charge pump 223 with smaller area is used, the driving capability of the charge pump 223 may not be strong enough to keep the program voltage V_{PP} at an expected level. In other words, in the time interval between the time point t₃ and the time point t₄, the program voltage V_{PP} on the antifuse control line AF continuously drops. At the time point t₄, the on period T_{ON1} is ended.

In the off period T_{OFF1} between the time point t₄ and the time point t₅, the word line driver 226 provides the off voltage V_{OFF} to the word line WL₁. Consequently, the select transistor M_{S} is turned off, and the select memory cell C₁₁ stops generating the program current. Consequently, in the off period T_{OFF1}, the program voltage V_{PP} from the charge pump 223 rapidly rises to the predetermined voltage (e.g., 6V). At the time point t₅, the off period T_{OFF1} is ended.

In the on period T_{ON2} between the time points t₅ and t₆, the word line driver 226 provides the on voltage V_{ON} to word line WL₁. Meanwhile, the select transistor M_{S} is turned on. Consequently, the selected memory cell C₁₁ generates the program current. In the on period T_{ON2}, although the program voltage V_{PP} drops, since the voltage is still high enough to cause the selected memory cell C₁₁ to generate the sufficient program current, the heating process can be successfully performed on the selected memory cell C₁₁. At the time point t₆, the on period T_{ON2} is ended.

In the off period T_{OFF2} between the time point t₆ and the time point t₇, and the off period T_{OFF3} between the time point t₀ and the time point t₉, the operation is similar to the off period T_{OFF1} between the time point t₄ and the time point t₅, and will not be described repeatedly herein.

In the on period T_{ON3} between the time point t₇ and the time point t₈, and the on period T_{ON4} between the time point t₉ and the time point t₁₀, the operation is similar to the on period T_{ON2}, and will not be described repeatedly herein.

In this embodiment, the timing controller 224 generates the timing control signal S_{CTRL}. The word line driver 226 provides the on voltage V_{ON} and the off voltage V_{OFF} to the activated word line according to the timing control signal S_{CTRL}. For example, the activated word line and the timing control signal S_{CTRL} may have the same waveform. Moreover, in the total time period of the plural on periods T_{ON1}, T_{ON2}, T_{ON3} and T_{ON4}, the program current and the program voltage V_{PP} is sufficient to rupture the gate oxide layer of the antifuse transistor M_{AF} in the selected memory cell C₁₁, and a heating process is completed. Consequently, the gate oxide layer of the antifuse transistor M_{AF} is in a solid rupture state.

As shown in FIG. 3B, the on period T_{ON1} is longer to assure that the gate oxide layer of the antifuse transistor M_{AF} in the selected memory cell C₁₁ is ruptured. Then, the on periods T_{ON2}, T_{ON3} and T_{ON4} are shorter to avoid large voltage drop from the charge pump 223, and assure that program current of the selected memory cell C₁₁ is sufficient to perform the heating process. Consequently, the gate oxide layer of the antifuse transistor M_{AF} can reach the solid rupture state. After the program cycle, it is assured that the selected memory cell C₁₁ is in the low-resistance storage state.

It is noted that, in some embodiments, the on period T_{ON1} can be shorter than the on periods T_{ON2}, T_{ON3} and T_{ON4} according to the characteristic of the memory cell. It is also noted that the number of the on periods, the length of each on period and the length of each off period are not restricted. The number of the on periods, the time width of the on period and the time width of the off period can be adjusted according to the driving capacity of the charge pump 223. Another example of the operations of the word bit driver 226 will be described as follows.

FIG. 3C is a schematic timing waveform diagram illustrating another signal when the memory cell of the antifuse-type non-volatile memory of the second embodiment undergoes the program action. For example, the program action is performed on the memory cell C₁₁.

Firstly, the antifuse-type non-volatile memory enters a program mode, and the program voltage generator 222 is enabled.

At the time point t_{X}, a program voltage enable signal ENV_{PP} is activated. Meanwhile, the program voltage V_{PP} outputted from the charge pump 223 of the program voltage generator 222 to the antifuse control line AF reaches a predetermined voltage (e.g., 6V). At the same time, the conducting voltage generator 114 issues the conducting voltage V_{FL} to the following control line FL.

At the time point ty, a write enable signal WE is activated. Meanwhile, the program action on the antifuse-type non-volatile memory can be started. The time interval between the time point ty and the time point t_{z} may be regarded as a program cycle. In the program cycle, the program cycle is divided into plural on periods T_{ON1}-T_{ON7} and plural off periods T_{OFF1}-T_{OFF6} by the word line driver 226 according to the timing control signal S_{CTRL}. The time widths of the on periods T_{ON1}-T_{ON7} are equal. The time widths of the off periods T_{OFF1}-T_{OFF6} are equal.

Please refer to FIG. 3C again. In the on periods T_{ON1}, T_{ON2} and T_{ON3} and the off periods T_{OFF1}, T_{OFF2} and T_{OFF3}, the program voltage V_{PP} is maintained at the predetermined voltage (e.g., 6V). In other words, the gate oxide layer of the antifuse transistor M_{AF} has not been ruptured. Consequently, no program current is generated in the region between the antifuse control line AF and the bit line BL₁.

In the on period T_{ON4}, the gate oxide layer of the antifuse transistor M_{AF} is ruptured. As mentioned above, the driving capability of the charge pump 223 is weaker. Consequently, the program voltage V_{PP} on the antifuse control line AF continuously drops. In addition, the program current is continuously decreased.

In the off period T_{OFF4}, the select memory cell C₁₁ stops generating the program current. That is, the charge pump 223 does not provide the program current. Consequently, in the off period T_{OFF4}, the program voltage V_{PP} of the charge pump 223 rapidly rises to the predetermined voltage (e.g., 6V).

In the on period T_{ON5}, the selected memory cell C₁₁ generates the program current. Consequently, in the on period T_{ON5}, the program voltage V_{PP} drops. However, the program voltage V_{PP} is high enough to generate the sufficient program current. Consequently, the heating process can be successfully performed on the selected memory cell C₁₁.

Similarly, in the off period T_{OFF5} and the off period T_{OFF6}, the program voltage V_{PP} is boosted to the predetermined voltage (e.g., 6V) by the charge pump 223 again. Similarly, in the on period T_{ON6} and the on period T_{ON7}, the program voltage V_{PP} is high enough to generate the sufficient program current. Consequently, the heating process can be successfully performed on the selected memory cell C₁₁.

In this embodiment, the timing controller 224 generates the timing control signal S_{CTRL}. The word line driver 226 provides the on voltage V_{ON} and the off voltage V_{OFF} to the activated word line according to the timing control signal S_{CTRL}. Moreover, in the total time period of the plural on periods T_{ON1}-T_{ON7}, the program current is sufficient to rupture the gate oxide layer of the antifuse transistor M_{AF} in the selected memory cell C₁₁, and a heating process is completed. Consequently, the gate oxide layer of the antifuse transistor M_{AF} is in a solid rupture state.

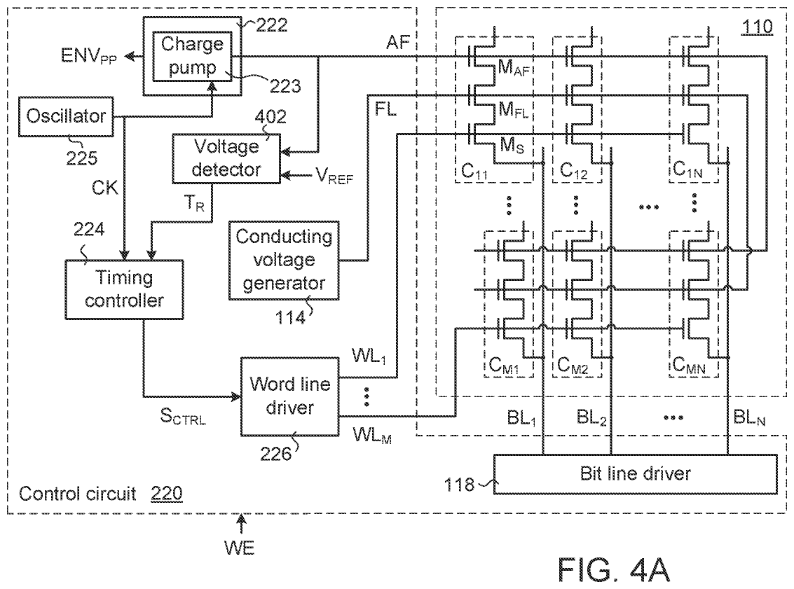

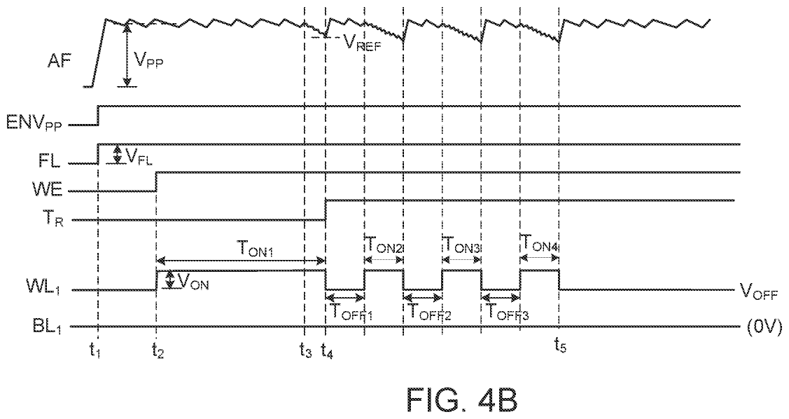

FIG. 4A is a schematic circuit diagram illustrating an antifuse-type non-volatile memory according to a third embodiment of the present invention. In comparison with the second embodiment, the control circuit 220 of the antifuse-type non-volatile memory of the third embodiment further comprises a voltage detector 402. For succinctness, only the connecting relationship between the voltage detector 402 and the associated components will be described as follows.

A first detection terminal of the voltage detector 402 is connected with the antifuse control line AF to receive the program voltage V_{PP}. A second detection terminal of the voltage detector 402 receives a reference voltage V_{REF}. An output terminal of the voltage detector 402 is connected with the timing controller 224. If the program voltage V_{PP} is lower than the reference voltage V_{REF}, a triggering signal T_{R} is activated by the voltage detector 402. When the triggering signal T_{R} is activated, the timing controller 224 generates the timing control signal S_{CTRL} to the word line driver 226 according to the clock signal CK. In the program cycle of the program action, the voltage provided from the word line driver 226 to the activated word line WL₁ is switched between the on voltage V_{ON} and the off voltage V_{OFF} according to the timing control signal S_{CTRL}.

FIG. 4B is a schematic timing waveform diagram illustrating associated signals when the memory cell of the antifuse-type non-volatile memory of the third embodiment undergoes the program action. For example, the program action is performed on the memory cell C₁₁.

Firstly, the antifuse-type non-volatile memory enters a program mode, and the program voltage generator 222 is enabled.

At the time point t₁, a program voltage enable signal ENV_{PP} is activated. Meanwhile, the program voltage V_{PP} outputted from the charge pump 223 of the program voltage generator 222 to the antifuse control line AF reaches a predetermined voltage (e.g., 6V). At the same time, the conducting voltage generator 114 issues the conducting voltage V_{FL} to the following control line FL.

At the time point t₂, a write enable signal WE is activated. Meanwhile, the program action on the antifuse-type non-volatile memory can be started. The time interval between the time points t₂ and t₅ may be regarded as a program cycle. At the time point t₂, the word line driver 226 provides the on voltage V_{ON} to the activated word line WL₁. In addition, an on period T_{ON1} is started.

At the time point t₃, the gate oxide layer of the antifuse transistor M_{AF} is ruptured. Consequently, a program current is generated in the region between the antifuse control line AF and the bit line BL₁. Consequently, the program voltage V_{PP} on the antifuse control line AF continuously drops. In addition, the program current is continuously decreased. At the time point t₄, the program voltage V_{PP} is lower than the reference voltage V_{REF}. Consequently, the triggering signal T_{R} is activated by the voltage detector 402. Meanwhile, the timing controller 224 activates the timing control signal S_{CTRL} to the word line driver 226 in response to the activated triggering signal T_{R}. Consequently, the on period T_{ON1} is ended. In the next program cycle, the voltage detector 402 determines whether the triggering signal T_{R} is activated according to the result of comparing the program voltage V_{PP} with the reference voltage V_{REF}. In other words, the voltage detector 402 determines the end time point of the on period T_{ON1}.

Similarly, in the off periods T_{OFF1}, T_{OFF2} and T_{OFF3}, the program voltage V_{PP} is boosted to the predetermined voltage (e.g., 6V) by the charge pump 223 again. Similarly, in the on periods T_{ON2}, T_{ON3} and T_{ON4}, the program voltage V_{PP} is high enough to generate the sufficient program current. Consequently, the heating process can be successfully performed on the selected memory cell C₁₁. In practice, the time width of the on period T_{ON1} is usually larger than the other on periods T_{ON2}, T_{ON3}, T_{ON4} when the antifuse-type non-volatile memory is equipped with the voltage detector 402.

In this embodiment, the timing controller 224 immediately activates the timing control signal S_{CTRL} for the word line driver to end the on period T_{ON1} when the triggering signal T_{R} is activated at the time point t₄. The word line driver 226 provides the on voltage V_{ON} and the off voltage V_{OFF} to the activated word line according to the timing control signal S_{CTRL}. Moreover, in the total time period of the plural on periods T_{ON1}, T_{ON2}, T_{ON3} and T_{ON4}, the program current is sufficient to rupture the gate oxide layer of the antifuse transistor M_{AF} in the selected memory cell C₁₁, and a heating process is completed. Consequently, the gate oxide layer of the antifuse transistor M_{AF} is in a solid rupture state.

In another embodiment, the triggering signal T_{R} and the timing control signal S_{CTRL} may be activated at different time point. For example, the timing controller 224 may activate the timing control signal S_{CTRL} with a predetermined delay time after the triggering signal T_{R} is activated. Consequently, the word line driver ends the on period T_{ON1} in response to the activation time of the timing control signal S_{CTRL}. That is to say, the on period T_{ON1} in FIG. 4B maybe ended after the time point T₄.

Furthermore, in comparison with the fixed time width of the on period T_{ON1} in FIG. 3B of the second embodiment, the on period T_{ON1} in FIG. 4B of the third embodiment may vary with the activation of the triggering signal T_{R}.

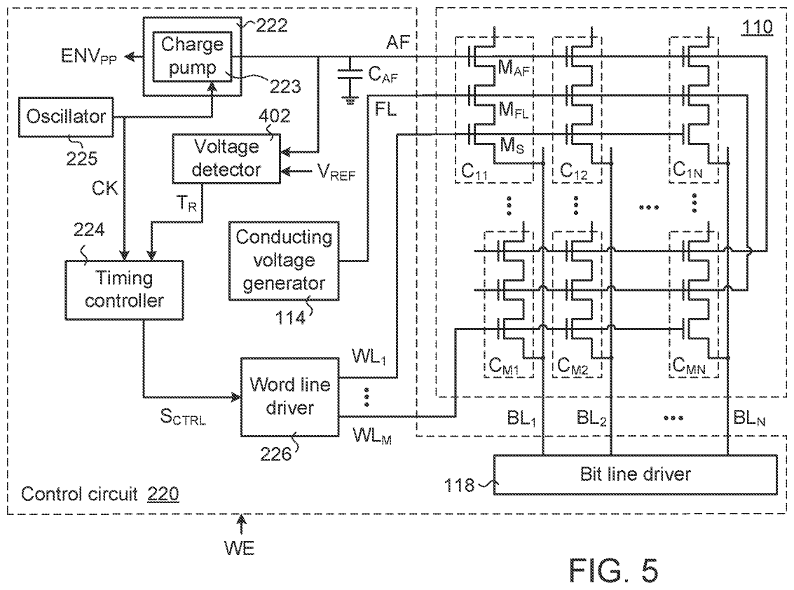

FIG. 5 is a schematic circuit diagram illustrating an antifuse-type non-volatile memory according to a fourth embodiment of the present invention. In comparison with third embodiment, the control circuit 220 of the antifuse-type non-volatile memory of the fourth embodiment further comprises a capacitor C_{AF}. The capacitor C_{AF} is connected between the antifuse control line AF and the ground terminal to enhance the driving capability of the charge pump 223. The connecting relationship between other components and the associated signals are similar to those of the third embodiment, and not redundantly described herein. Of course, in a variant example of the antifuse-type non-volatile memory of the first embodiment or the second embodiment, the antifuse-type non-volatile memory of the fourth embodiment further comprises a capacitor C_{AF}.

From the above descriptions, the present invention provides an antifuse-type non-volatile memory. During the program cycle of the program action, the timing controller 224 generates the timing control signal S_{CTRL}. The word line driver 226 provides the on voltage V_{ON} and the off voltage V_{OFF} to the activated word line according to the timing control signal S_{CTRL}. Moreover, in the total time period of the plural on periods T_{ON1}, T_{ON2}, T_{ON3} and T_{ON4}, the program current is sufficient to rupture the gate oxide layer of the antifuse transistor M_{AF} in the selected memory cell C₁₁, and a heating process is completed. Consequently, the gate oxide layer of the antifuse transistor M_{AF} is in a solid rupture state. In other words, the program action can be performed on the selected memory cell C₁₁ successfully.

In the above embodiments, each of the memory cells C₁₁˜C_{MN} in the antifuse-type memory cell array 110 is a 3T memory cell. It is noted that numerous modifications and alterations may be made while retaining the teachings of the invention. For example, in another embodiment, each of the memory cells in the antifuse-type memory cell array 110 is a 2T memory cell. That is, the 2T memory cell comprises antifuse transistor M_{AF} and the select transistor M_{S} only. The first drain/source terminal of the select transistor M_{S} is connected with the corresponding bit line. The gate terminal of the select transistor M_{S} is connected with the corresponding word line. The first drain/source terminal of the antifuse transistor M_{AF} is coupled to the second drain/source terminal of the select transistor M_{S}. The gate terminal of the antifuse transistor M_{AF} is connected with the antifuse control line AF. The second drain/source terminal of the antifuse transistor M_{AF} is in the floating state. Since the antifuse-type memory cell array with the 2T memory cells is not equipped with the following control line FL, the conducting voltage generator can be omitted from the control circuit of the antifuse-type non-volatile memory.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An antifuse-type non-volatile memory, comprising:
an antifuse-type memory cell array comprising a first memory cell, wherein the first memory cell is connected with an antifuse control line, a first word line and a first bit line, and the first memory cell comprises an antifuse transistor and a select transistor, wherein a first drain/source terminal of the select transistor is connected with the first bit line, a gate terminal of the select transistor is connected with the first word line, a first drain/source terminal of the antifuse transistor is coupled to a second drain/source terminal of the select transistor, and a gate terminal of the antifuse transistor is connected with the antifuse control line; and
a control circuit comprising:
an oscillator generating a clock signal;
a program voltage generator comprising a charge pump, wherein the charge pump is connected with the oscillator to receive the clock signal, wherein when a program action is performed, a supply voltage is boosted to a program voltage by the charge pump according to the clock signal, and the program voltage is provided to the antifuse control line;
a timing controller connected with the oscillator, wherein the timing controller receives the clock signal and generates a timing control signal;
a word line driver connected with the first word line of the antifuse-type memory cell array, wherein the word line driver is connected with the timing controller to receive the timing control signal; and
a bit line driver connected with the first bit line of the antifuse-type memory cell array, wherein in a program cycle of the program action, the first word line is activated by the word line driver, and the first bit line is activated by the bit line driver, so that the first memory cell is a selected memory cell,
wherein in the program cycle of the program action, the word line driver issues a pulse signal to the first word line according to the timing control signal, wherein a first level of the pulse signal is an on voltage, and a second level of the pulse signal is an off voltage, wherein after the program cycle, a storage state of the first memory cell is switched from a high-resistance storage state to a low-resistance storage state.

2. The antifuse-type non-volatile memory as claimed in claim 1, wherein the first memory cell further comprises a following transistor, and the control circuit comprises a conducting voltage generator, wherein a first drain/source terminal of the following transistor is connected with the second drain/source terminal of the select transistor, a second drain/source terminal of the following transistor is connected with the first drain/source terminal of the antifuse transistor, a gate terminal of the following transistor is connected with a following control line, and the conducting voltage generator is connected with the following control line, wherein when the program action is performed, the conducting voltage generator provides a conducting voltage to the following control line, and the following transistor is in a conducting state, so that the antifuse transistor is coupled to the select transistor.

3. The antifuse-type non-volatile memory as claimed in claim 1, wherein the program cycle is divided into plural on periods and plural off periods by the word line driver according to the pulse signal, wherein the word line driver provides the on voltage to the first word line during the plural on periods, and the word line driver provides the off voltage to the first word line during the plural off periods.

4. The antifuse-type non-volatile memory as claimed in claim 3, wherein during a first on period of the plural on periods, a gate oxide layer of the antifuse transistor in the selected memory cell is ruptured, and a program current is generated, wherein during the on periods other than the first on period, the selected memory cell is subjected to a heating process by the program current, so that the gate oxide layer of the antifuse transistor is in a solid rupture state, wherein during the plural off periods, the program current is not generated by the selected memory cell.

5. The antifuse-type non-volatile memory as claimed in claim 3, wherein a time width of a first on period is larger than a time width of each of the on periods other than the first on period.

6. The antifuse-type non-volatile memory as claimed in claim 3, wherein time widths of the plural on periods are identical, wherein in a total time period of the plural on periods, the program current is sufficient to rupture a gate oxide layer of the antifuse transistor in the selected memory cell, and a heating process is completed, so that the gate oxide layer of the antifuse transistor is in a solid rupture state.

7. The antifuse-type non-volatile memory as claimed in claim 1, wherein the control circuit further comprises a capacitor, and the capacitor is connected between the antifuse control line and a ground terminal.

8. The antifuse-type non-volatile memory as claimed in claim 1, wherein the control circuit further comprises a voltage detector, wherein a first detection terminal of the voltage detector is connected with the antifuse control line to receive the program voltage, a second detection terminal of the voltage detector receives a reference voltage, and an output terminal of the voltage detector is connected with the timing controller.

9. The antifuse-type non-volatile memory as claimed in claim 8, wherein the program cycle is divided into plural on periods and plural off periods by the word line driver according to the pulse signal, wherein the word line driver provides the on voltage to the first word line during the plural on periods, and the word line driver provides the off voltage to the first word line during the plural off periods.

10. The antifuse-type non-volatile memory as claimed in claim 9, wherein an end time point of a first on period of the plural on periods is determined by the voltage detector.

11. The antifuse-type non-volatile memory as claimed in claim 10, wherein if the program voltage is lower than the reference voltage, a gate oxide layer of the antifuse transistor in the selected memory cell is ruptured, a program current is generated, and a triggering signal is activated by the voltage detector.

12. The antifuse-type non-volatile memory as claimed in claim 11, wherein when the triggering signal is activated, the first on period of the plural on periods is ended by the word line driver under control of the timing controller.

13. The antifuse-type non-volatile memory as claimed in claim 11, when the triggering signal is activated, the timing controller activates the timing control signal with a predetermined delay time after the triggering signal is activated, and the first on period of the plural on periods is ended by the word line driver in response to a activation time of the timing control signal.

14. The antifuse-type non-volatile memory as claimed in claim 11, wherein during the on periods other than the first on period, the selected memory cell is subjected to a heating process by the program current, so that the gate oxide layer of the antifuse transistor is in a solid rupture state, wherein during the plural off periods, the program current is not generated by the selected memory cell.

15. The antifuse-type non-volatile memory as claimed in claim 10, wherein a time width of the first on period is larger than a time width of each of the on periods other than the first on period.
